(19) United States
(12) Patent Application Publication
(10) Pub. No.: US 2014/0118985 A1
(43) Pub. Date: May 1, 2014

(54) PHONE CONSTRUCTION/LENS DESIGN TO REDUCE LENS BOARDERS

(71) Applicant: MOTOROLA MOBILITY LLC, Libertyville, IL (US)

(72) Inventor: Brian J. Hassember, Gurnee, IL (US)

(73) Assignee: MOTOROLA MOBILITY LLC, Libertyville, IL (US)

(21) Appl. No.: 13/664,451

(22) Filed: Oct. 31, 2012

(51) Int. Cl. H05K 5/02

(52) U.S. Cl. 361/814

(57) ABSTRACT

An improved compact mobile phone or other electronic communications device 102 can be provided with reduced lens borders 154 and 156 and a larger viewable display 110 with an edge to edge display lens 114. The display lens can have stepped lateral edges 116 and 118 which can provide lens steps comprising stepped tabs and can have borderless longitudinal edges 120 and 122.

### BACKGROUND OF THE INVENTION

1. Field of the Disclosure

The disclosure relates in general to electronic communication devices and more particularly to a larger lens for mobile electronic devices, such as a mobile telephone.

2. Background Art

Mobile phones and other electronic devices are very useful for: telephone calls, internet usage, e-mailing, texting, downloading, photography, video conferencing, surfing and searching the internet or world wide web, retrieving, storing and viewing information, social networking, calculating, computing, playing games, etc.

Many conventional portable electronic devices have small display lenses or screens which are difficult to read. Furthermore, it is difficult to input information and data on small display touch screens and other small displays.

Conventional display lenses and screens are surrounded by a wide border, frame, and/or bezel. Components such as a display unit, touch sensor, and cover glass can be mounted within the frame. The surrounding wide border, wide frame, and/or bezel can take up a large portion of the entire front display, thereby decreasing the viewable size of the display lens or touch screen. It is desirable that the border, frame, and/or bezel be of a minimum size, so the display area can be optimized to occupy nearly the entire display surface or front surface for better view.

Furthermore, it is important that the portable electronic device deliver good audio and haptics with a comfortable feel, touch feedback and sensitivity to the user. Many conventional hand held electronic devices and touch screen mobile devices, however, do not provide effective, comfortable, localized haptics and audio at the user interface. Moreover, many conventional hand held electronic devices are often difficult to assemble and expensive to manufacture.

Conventional zoom and magnification techniques to enlarge or decrease the size of text or graphics on a display screen of a mobile electronic device often require touching, tapping, clicking and partially blocking the touch screen display. It is therefore desirable that the display lens or screen be as large as practical.

As display screens get larger, so does the overall width of the phone. Therefore, it is preferred to have a “borderless” design with a reduced border or frame to enlarge the display active area to the edges of the phone for a smaller phone width and better comfort in hand. There is a significant market for mobile electronic devices with large displays, as well as, a unique, thin, and cost-effective mobile electronic device.

It is desirable to create an improved mobile electronic device which enables a new and larger display screen to use with different applications and the user interface of the mobile electronic devices. It is also desirable to provide a new phone construction and lens design to reduce lens borders, which overcomes most, if not all of the preceding disadvantages.

### BRIEF DESCRIPTION OF THE DRAWINGS

FIG. 1 is a cross-sectional perspective view of a mobile electronic communications device with a new construction and lens design to reduce lens borders in accordance with principles of the present invention.

FIG. 2 is a reduced cross-sectional side view of the mobile electronic communications device with a new construction and lens design to reduce lens borders in accordance with principles of the present invention.

FIG. 3 is a front view of the mobile electronic communications device with a new construction and lens design to reduce lens borders in accordance with principles of the present invention.

FIG. 4 is a reduced cross-sectional bottom view of the mobile electronic communications device with a new construction and lens design to reduce lens borders in accordance with principles of the present invention.

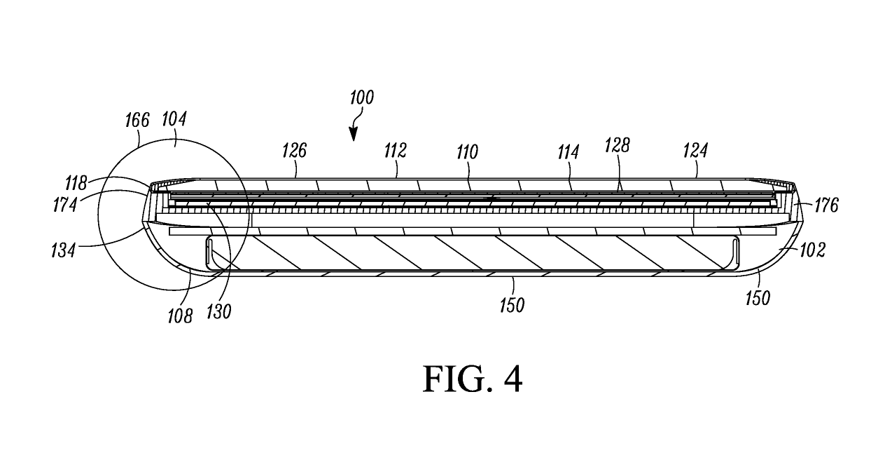

FIG. 5 is an enlarged fragmentary cross-sectional bottom view of part of the mobile electronic communications device with a new construction and lens design to reduce lens borders in accordance with principles of the present invention.

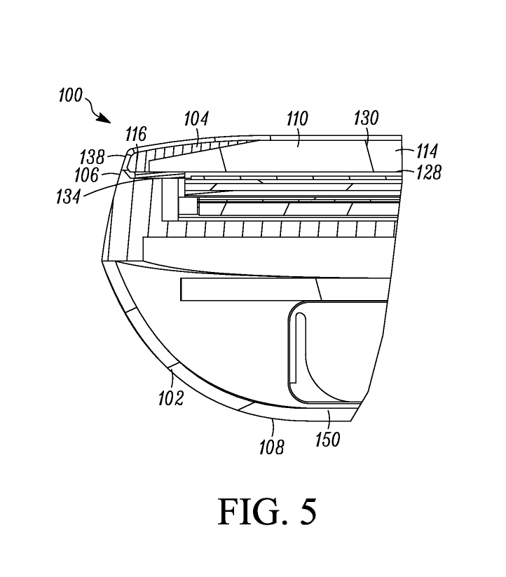

FIG. 6 is a perspective assembly view of the top stepped edge of the lens before being inserted into the top portion of the front housing of the mobile electronic communications device in accordance with principles of the present invention.

FIG. 7 is a perspective assembly view of the top stepped edge of the lens after being inserted into the top portion of the front housing of the mobile electronic communications device in accordance with principles of the present invention.

FIG. 8 is a perspective assembly view of the lens after being fully inserted into the front housing of the mobile electronic communications device in accordance with principles of the present invention.

FIG. 9 is an enlarged fragmentary perspective assembly view of the top stepped edge of the lens after being inserted into the top portion of the front housing of the mobile electronic communications device in accordance with principles of the present invention.

FIG. 10 is an enlarged fragmentary perspective assembly view of the bottom stepped edge of the lens after being inserted into the bottom portion of the front housing of the mobile electronic communications device in accordance with principles of the present invention.

FIG. 11 is a perspective assembly view of the lens in the front housing before the bottom stepped edge of the lens is inserted into the bottom portion of the back housing of the mobile electronic communications device in accordance with principles of the present invention.

FIG. 12 is a perspective assembly view of the lens in the front housing showing the bottom stepped edge of the lens being inserted into the bottom portion of the back housing of the mobile electronic communications device in accordance with principles of the present invention.

FIG. 13 is a perspective assembly view of the lens and front housing after being fully inserted into the back housing of the mobile electronic communications device in accordance with principles of the present invention.

FIG. 14 is an enlarged fragmentary perspective assembly view of the bottom stepped edge of the lens and front housing after being fully inserted into the back housing of the mobile electronic communications device in accordance with principles of the present invention.

FIG. 15 is an exploded assembly view of the mobile electronic communications device with a new construction and lens design to reduce borders in accordance with principles of the present invention.

### DETAILED DESCRIPTION OF THE INVENTION

An improved electronic communications device is provided with a new phone construction and lens design to reduce lens borders, which enables a new and larger viewing (viewable) area of a display screen to use with different applications and the user interface of the mobile electronic devices, and which is effective, economical, and easy to use.

The new phone construction can be provided with a special construction with mechanical features at the top and bottom and a special method (process) for attaching and locating the display lens, along with a housing, to the phone's housing. The glass lens can be first inserted into a housing. It can be inserted such that lens steps (mechanical steps) are attached at top and bottom ends of the glass lens. Advantageously, the novel phone construction can secure the display lens at the top and bottom ends with a housing ledge, in order to secure the lens with mechanical features at the top and bottom. Desirably, this novel phone construction can secure the display lens to the phone using mechanical features only at the ends, allowing for a minimal lens adhesive. These mechanical steps can be used to attach the lens, along with the housing, to the phone housing structure. The process of attaching the lens to the housing of the mobile phone is like a ski boot, first the toe can be inserted and pivoted, and then the heel can be connected.

The new phone construction can utilize a unique double ski boot-like design. The assembly can allow for a lens assembly to the front housing and chassis to secure the lens via an adhesive and an undercut on short side (ski boot 1). This subassembly can then be assembled to the rear housing where the lens and chassis subassembly can be secured via an undercut with fasteners such as screws, adhesive, snaps, etc. (ski boot 2).

Molded and mechanical toe in features providing tabs can be provided on the phone housing structure to accept the lens steps (mechanical steps).

The novel phone construction can be a cover glass lens attachment design having a cover glass lens with stepped tabs along the top and bottom to mechanically secure the lens to the phone. The novel phone construction can have front and rear housings with undercut features to accept the lens tabs. Furthermore, the novel phone construction can have a lens edge exposed on left and right sides for improved feel and look.

Along the sides of the novel phone construction, a minimal lens adhesive can be used to seal the display area from liquid and dust. The adhesive need not be relied on for securing the lens to the phone. These mechanical features are machined steps within the glass lens which will toe in under ledges formed by the phone's housing structure. This allows for a minimal lens adhesive along the sides, thereby reducing the product width.

This novel phone construction achieves a reduced phone width and a preferred lens to edge look. The new phone construction supports a highly desirable lens to edge concept that minimizes the parting line. Furthermore, the top and bottom ends create a natural path to protect the lens. Moreover, the novel lens to edge provides product differentiation and decreases overall width.

In the illustrative embodiment, an electronic communications device, is provided with a lens and at least one housing for holding the lens. Preferably, the lens has at least one stepped edge and the housing has a ledge for securing the stepped edge of the lens.

The following is a detailed description and explanation of the preferred embodiments of the invention and best modes for practicing the invention.

Referring to the drawings, a lens assembly 100 can be provided for an electronic communications device 102. The electronic communications device can be moveable and pivotable from a landscape orientation mode (landscape mode or landscape orientation) to a portrait orientation mode (portrait mode or portrait orientation) and vice versa. The electronic communications device can have a display module 104 and a chassis 106 which can comprise a modular housing assembly 108 to securely hold the display module. The display module can comprise an electronic visual display 110 for displaying images 112. The electronic visual display can comprise an elongated, generally rectangular, stepped display lens 114 with opposite stepped lateral edges 116 and 118 at the top end 117 and bottom end 119 of the lens which can provide lens step (mechanical steps) comprising stepped tabs and can have opposite borderless longitudinal edges 120 and 122 which can extend longitudinally between and integrally connect the stepped lateral edges. The stepped lateral edges can comprise substantially symmetrical stepped edges including a stepped top lateral edge 116 and a stepped bottom lateral edge 118.

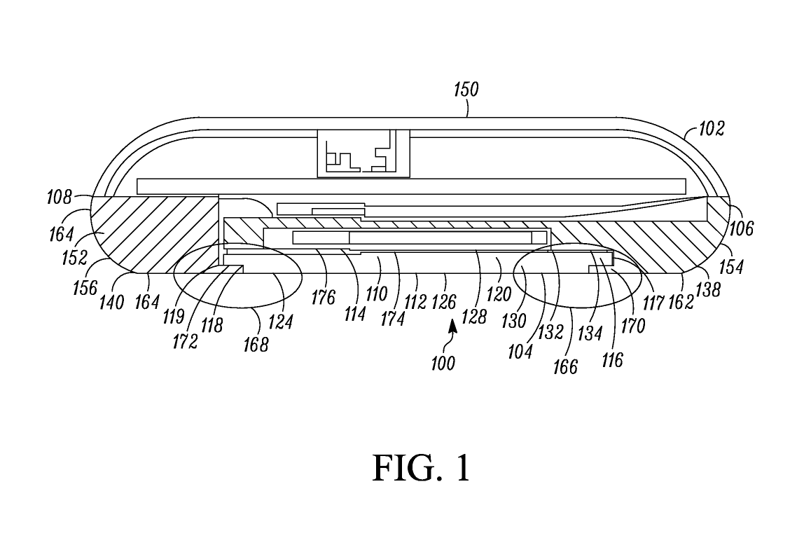

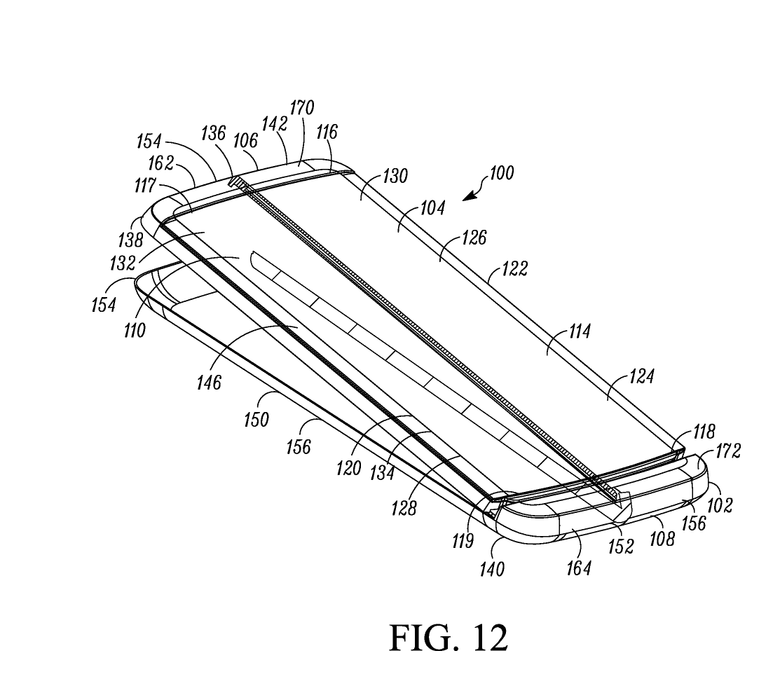

The display lens can comprise a user interface (UI) 124 (FIGS. 1-3) and can have a touch sensitive haptic elongated front lens surface 126. The display lens can comprise: a glass lens, transparent lens, touch sensitive lens, haptic lens, screen, impact-resistant screen, display screen, touchscreen, screen with an accelerator, monitor, light emitting display, or combinations of any of the preceding. The touch sensitive haptic lens surface can provide an input surface and be positioned opposite a back surface 128 of the lens. The touch sensitive surface of the lens can have touch sensors 130 which generate a signal in response to a manually engageable haptic input from a user when the user touches the touch sensitive surface of the lens with a finger. Touch sensors can be located behind the front surface of the lens or behind the back surface of the lens. The user interface and a display module can comprise a light emitting display for emitting light forming an image on the lens in response to the signal. The user interface can also have a display bezel 132 which can comprise a back plate 134 (back plate portions) that can provide part of the front housing and can cooperate with the modular housing assembly to support and securely hold the display lens, optionally with adhesive or fasteners 136 (FIG. 12). The display module can also have piezoelectric elements that can provide haptics with direct piezoelectric bending action for allowing substantial transfer of mechanical vibration energy.

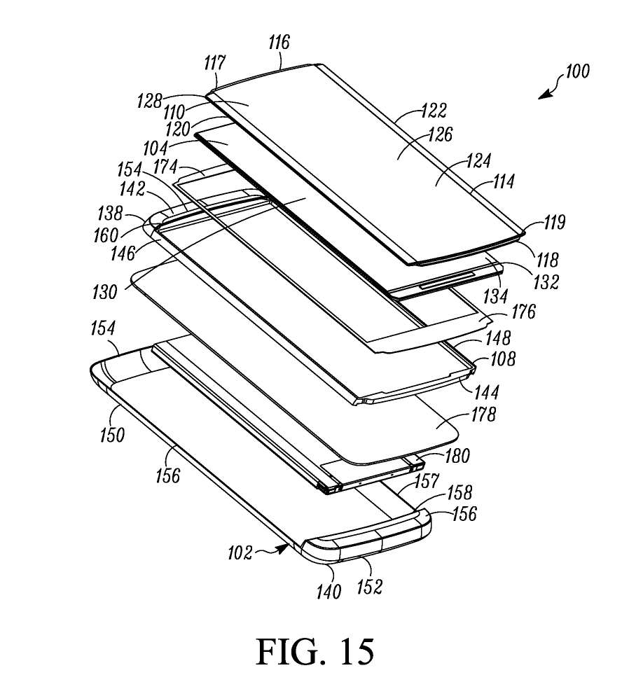

The modular housing assembly can have a front housing 138 and a back housing 140 (FIGS. 1, 3, 11-13, and 15) which can matingly engage and couple with the front housing. The front housing can have substantially parallel front lateral housing-edges 142 and 144 and substantially parallel front longitudinal housing edges 146 and 148 which can extend between and integrally connect the front lateral housing-edges. The housing can include the bezel and back plate. The back housing can provide a rearward housing with a back surface 150 which can comprise the back of the modular housing assembly and electronic communications device. The back housing can have substantially parallel back lateral housing-edges 152 and 154 and substantially parallel back longitudinal housing edges 156 and 157 (FIG. 15) which can extend between and integrally connect the back lateral housing-edges.

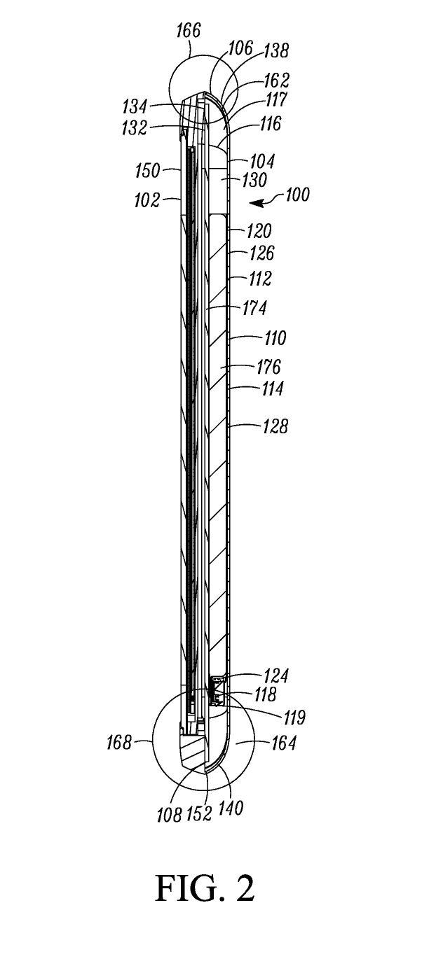

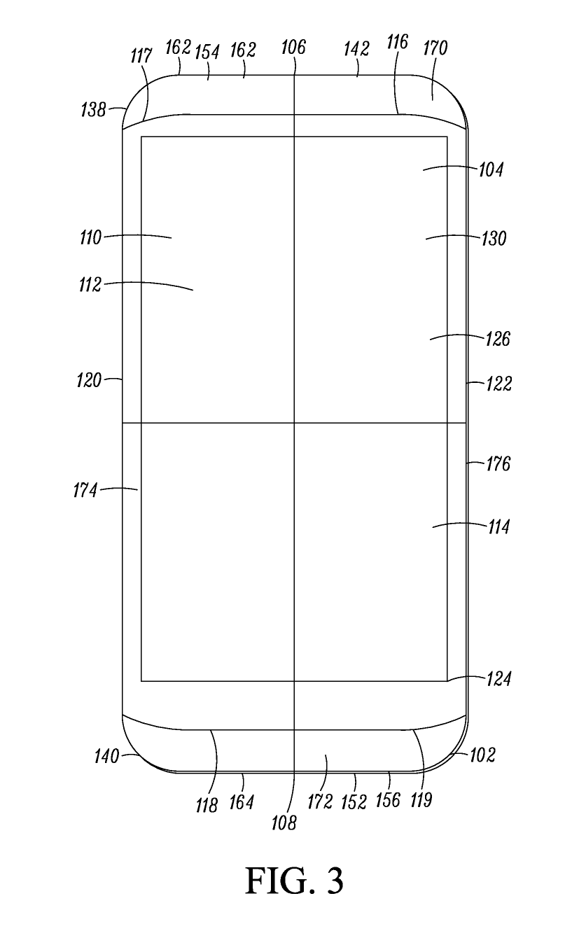

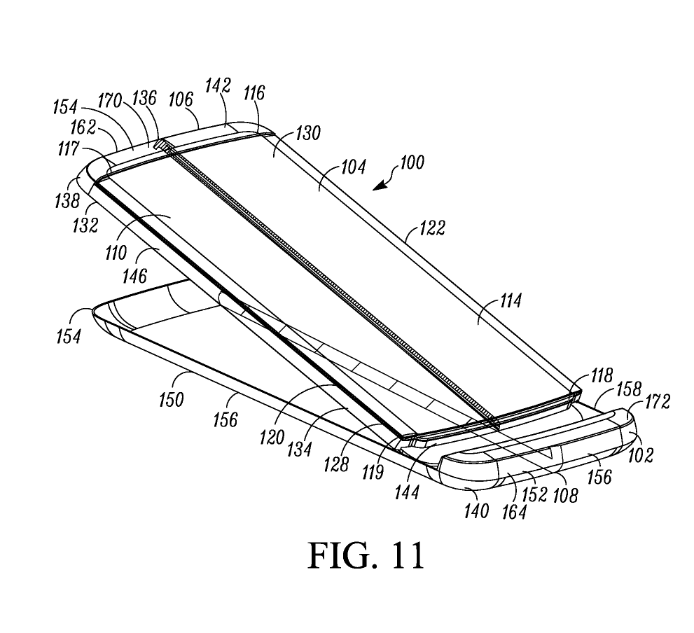

When the lens assembly and electronic communications device are assembled, the back housing-edges can be aligned in registration with the front housing-edges. One of the front lateral housing edges can comprise a top edge 142 (FIGS. 3 and 11) that can be positioned at a level above the other edges of the front housing when the electronic communications device is positioned or lying on its back (back surface). Furthermore, one of the back lateral housing edges can comprise a bottom edge 152 that can be positioned at a level above the other edges of the back housing when the electronic communications device is positioned or lying on its back (back surface). The top edge and bottom edge can be positioned generally opposite each other and can comprise generally opposite lateral border sections 154 and 156 which can provide substantially symmetrical lateral stepped edge-engaging portions 158 and 160 (FIG. 15) that laterally extends along, overlaps and borders the stepped lateral edges of the lens. The top border section, which can sometimes be referred to as a top border, eyebrow, or forehead, and the bottom border section, which can sometimes be referred to as a bottom border, chin, or foot, can sometimes be wider, narrower, thinner, thicker, or of different heights and sizes. The stepped edge-engaging portions can preferably comprise opposite overlapping outer ledges 162 and 164 which can overlap and securely engage the stepped edges of the display lens. The overlapping ledges can cooperate with the bezel or back plate portions of the housing to provide pockets 166 and 168 (FIGS. 1 and 2) which can define stepped edges-receiving slots that can be complementary to and securely receive the stepped edges of the display lens. In the illustrative embodiment, the top and bottom edges can have outwardly facing surfaces 170 and 172 which can be positioned generally flush with and in substantial coplanar alignment with the front lens surface.

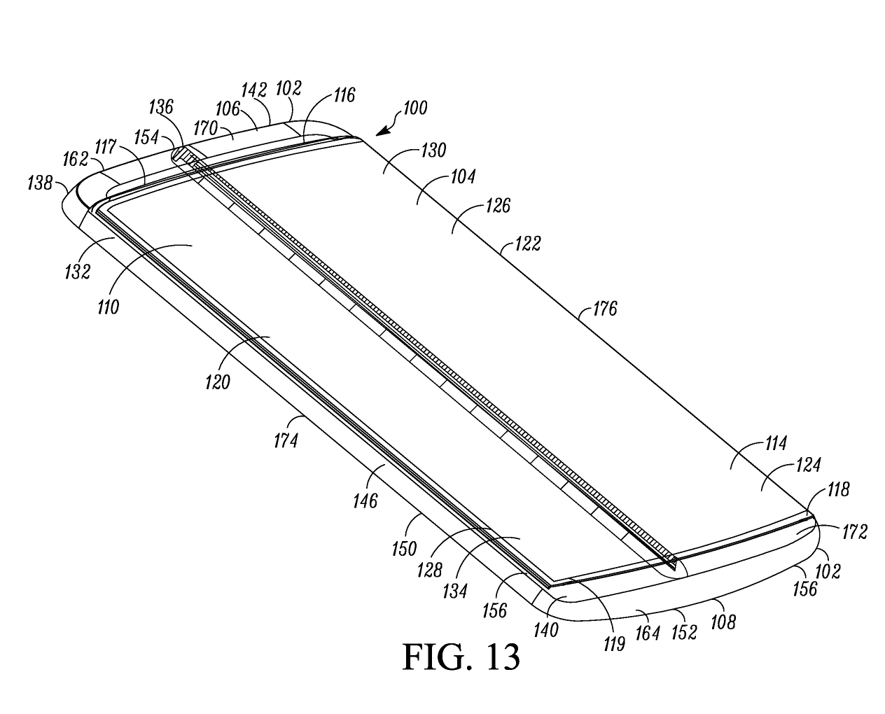

In the preferred embodiment, the borderless longitudinal edges of the display lens can comprise exposed edges that can be spaced away from and at right angles to the lateral border sections. If desired, the exposed longitudinal edges can be recessed and positioned laterally inwardly from the lateral edges of housing. The unexposed edges can be fully visible to a user. Preferably, a liquid-imperious seal 174 (FIGS. 3 and 13) comprising a transparent adhesive 176 can seal the exposed edges to the modular housing assembly. The transparent adhesive can comprise an impact-resistant material, such as for example an ultraviolet (UV) resin, to protect the exposed longitudinal edges from impact if the mobile electronic communications device is accidentally dropped to help prevent and minimize breaking, cracking, or other damage to the lens. The lens surface can extend laterally entirely across or almost across the modular housing assembly from longitudinal edge to longitudinal edge to a position above the longitudinal housing-sides.

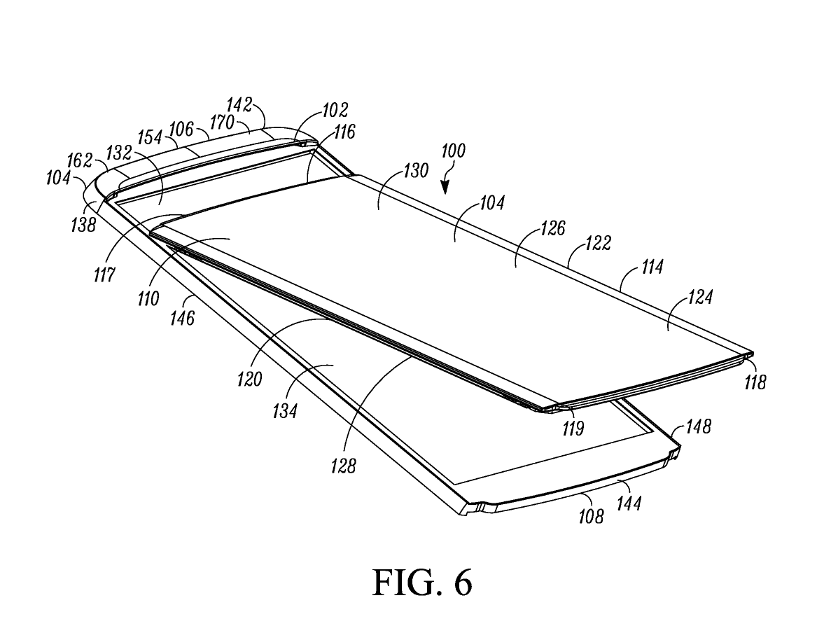

FIGS. 6-8 and 11-13 illustrate steps that can be used to assemble the lens assembly and display module of the electronic communications device. The lens can be stepped at the top and bottom ends to secure the lens to the phone or other electronic communications device. Lens adhesive which provides a seal can be placed along the sides of the lens. Less less adhesive is needed since the lens is held at the ends. The lens assembly reduces, decreases, and virtually eliminates longitudinal side borders for the lens.

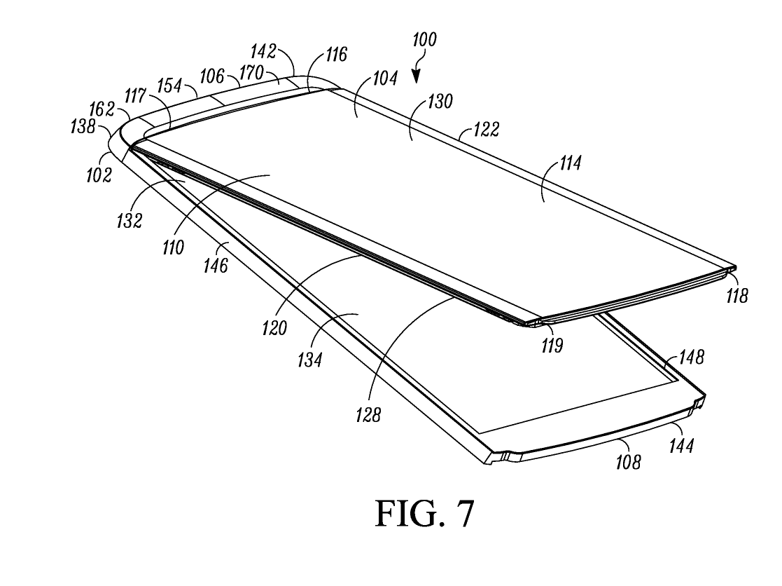

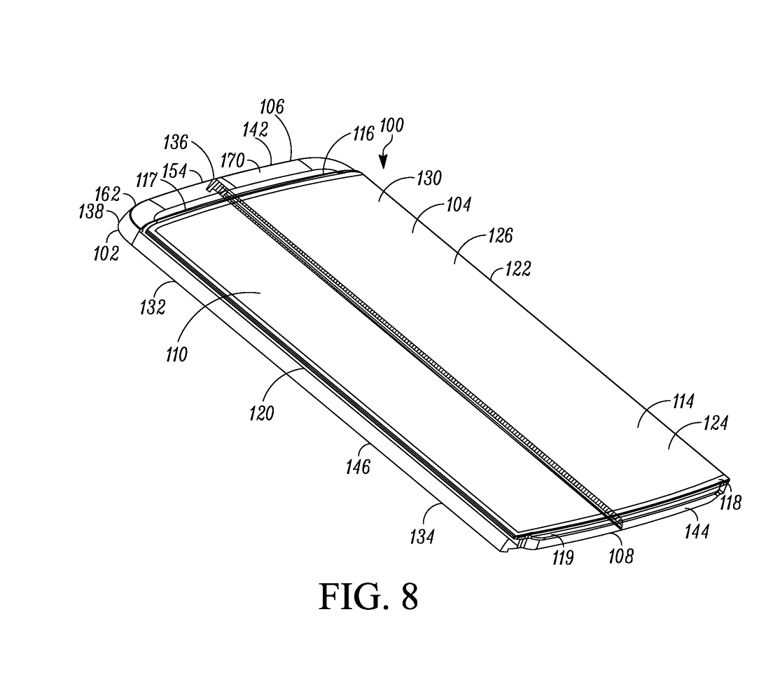

FIG. 6 is a perspective assembly view of the top stepped edge of the lens before being inserted into the top portion of the front housing of the mobile electronic communications device. FIG. 7 is a perspective assembly view of the top stepped edge of the lens after being inserted into the top portion of the front housing of the mobile electronic communications device. FIG. 8 is a perspective assembly view of the lens after being fully inserted into the front housing of the mobile electronic communications device.

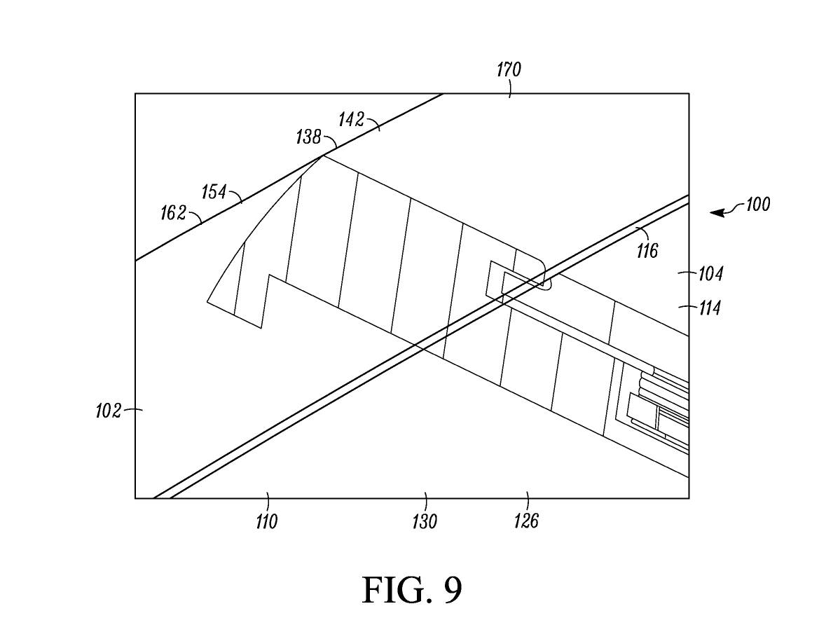

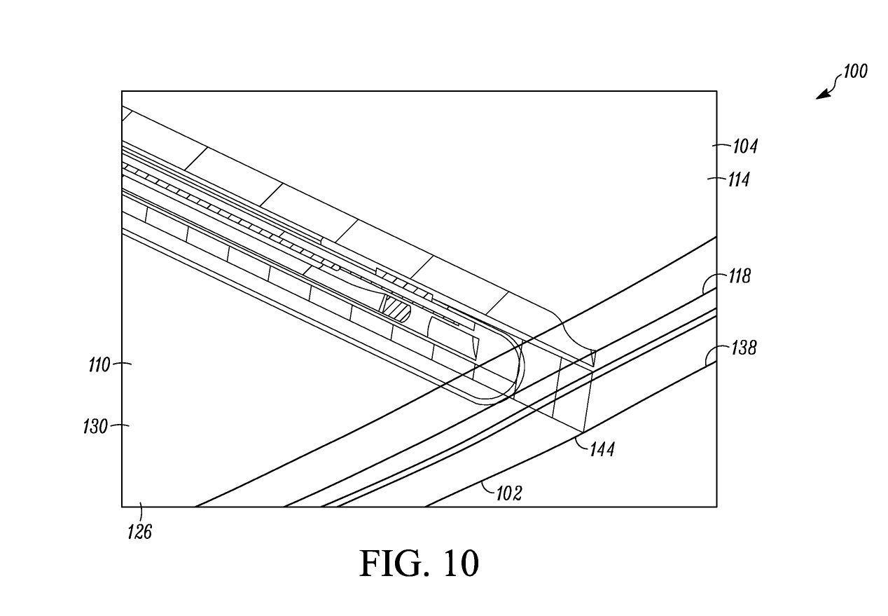

FIG. 9 is an enlarged fragmentary perspective assembly view of the top stepped edge of the lens after being inserted into the top portion of the front housing of the mobile electronic communications device. FIG. 10 is an enlarged fragmentary perspective assembly view of the bottom stepped edge of the lens after being inserted into the bottom portion of the front housing of the mobile electronic communications device.

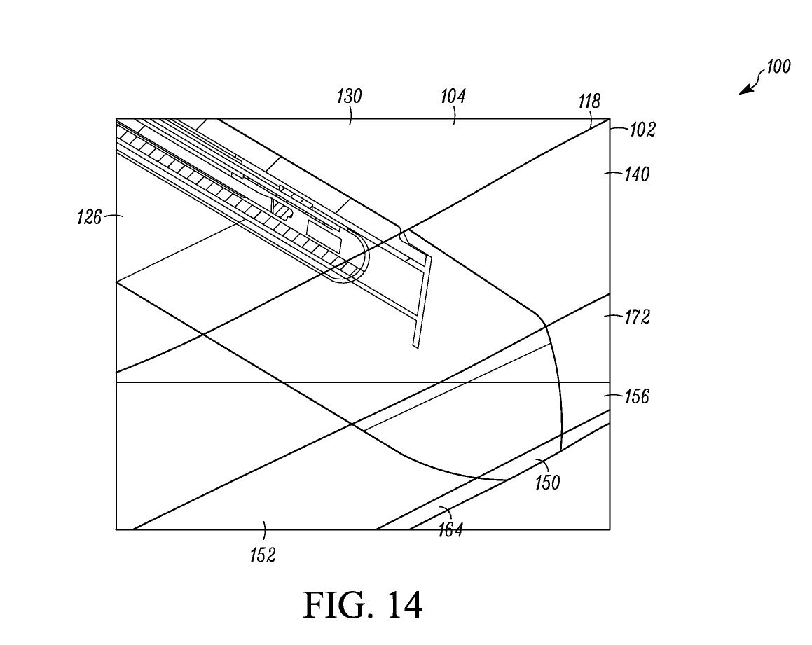

FIG. 11 is a perspective assembly view of the lens in the front housing before the bottom stepped edge of the lens is inserted into the bottom portion of the back housing of the mobile electronic communications device. FIG. 12 is a perspective assembly view of the lens in the front housing showing the bottom stepped edge of the lens being inserted into the bottom portion of the back housing of the mobile electronic communications device. FIG. 13 is a perspective assembly view of the lens and front housing after being fully inserted into the back housing of the mobile electronic communications device. FIG. 14 is an enlarged fragmentary perspective assembly view of the bottom stepped edge of the lens and front housing after being fully inserted into the back housing of the mobile electronic communications device.

FIG. 15 is an exploded assembly view of the lens assembly, display module and other components of the electronic communications device, including a printed circuit board (PCB) 178 and a battery pack 180.

The electronic communications device can comprise a portable electronic device, such as: a radiotelephone, cellular (cell) phone, mobile phone, smart phone, qwerty phone, flip phone, slider phone, android phone, tablet phone, camera phone, clamshell device, portable networking device, portable gaming device, mobile communications device, personal digital assistant (PDA), wireless e-mail device, a two way pager, internet communication device, android tablet, ipod, ipad, kindle, electronic reading device, incoming call notifier, answering machine, or combinations of any of the preceding.

The images displayed on the electronic display comprising a screen can comprise one or more of the following: graphics, color graphics, black graphics, moving graphics, text, numbers, alpha numeric images, characters, icons, animation, video clips, logos, photographs, decorations, designs, symbols, information, and data.

Among the many advantages of the mobile electronic communications device with a new construction and lens design to reduce lens borders are:
1. Superior capability.
2. Superb performance.
3. Allows for a larger screen.
4. Provides a more compact phone with a larger display.
5. Decreased borders.
6. Simpler with less parts to assemble.
7. Reliable.
8. User friendly.
9. Easy to use.
10. Durable.
11. Economical.
12. Attractive.
13. Efficient.
14. Effective.

Although embodiments of the invention have been shown and described, it is to be understood that various modifications, substitutions, and rearrangements of parts, components, and/or process (method) steps, as well as other uses of the mobile electronic communications device with a new construction and lens design to reduce lens borders can be made by those skilled in the art without departing from the novel spirit and scope of this invention.

What is claimed is:

1: A lens assembly for an electronic communications device, comprising:
an electronic communications device having a lens and at least one housing for holding said lens;
said lens having at least one stepped edge; and
said housing having a ledge for securing said stepped edge of said lens.

2: A lens assembly for an electronic communications device in accordance with claim 1 wherein:
said lens has an exposed edge, and
said exposed edge is different than said stepped edge.

3: A lens assembly for an electronic communications device in accordance with claim 1 wherein:
said housing has sides; and
said lens has at least one visible edge that extends to one of said sides.

4: A lens assembly for an electronic communications device in accordance with claim 1 wherein said lens has at least one borderless edge.

5: A lens assembly for an electronic communications device in accordance with claim 1 wherein said lens has a borderless portion extending entirely across said housing.

6: A lens assembly for an electronic communications device in accordance with claim 1 wherein said ledge comprises a stepped edge-engaging portion for matingly engaging and overlapping said stepped edge of said lens.

7: A lens assembly for an electronic communications device in accordance with claim 1 wherein:
said lens has opposed stepped edges; and
said housing has opposed ledges for securing engaging said stepped edges.

8: A lens assembly for an electronic communications device in accordance with claim 1 wherein said stepped edges comprise stepped tabs.

9: A lens assembly for an electronic communications device in accordance with claim 1 wherein said lens comprises an electronic visual display selected from the group consisting of: a display lens, glass lens, transparent lens, touch sensitive lens, haptic lens, screen, impact-resistant screen, display screen, touchscreen, screen with an accelerator, user interface, monitor, light emitting display, and combinations of any of the preceding.

10: A lens assembly for an electronic communications device in accordance with claim 1 wherein said electronic communications device comprises a portable electronic device selected from the group consisting of: a radiotelephone, cellular (cell) phone, mobile phone, smart phone, qwerty phone, flip phone, slider phone, android phone, tablet phone, camera phone, clamshell device, portable networking device, portable gaming device, mobile communications device, personal digital assistant (PDA), wireless e-mail device, a two way pager, internet communication device, android tablet, ipod, ipad, kindle, electronic reading device, electronic photo frame, digital photo frame, digital picture frame, video player, audio player, electronic calculator, electronic monitor, blackberry, tablet device, video device, computer, netbook, data sharing device, wireless device, handheld electronic communications device, global positioning system (GPS), navigation device, transmitting device, electronic receiving device, electronic planner, workout planner, electronic calendar, scheduling device, music player, MP3 player, performance monitor, golf tracker, incoming call notifier, answering machine, statistical storage device, data storage device, information storage device, cadence sensor, goal setting device, fitness tracker, exercise monitor, sports monitor, workout frequency monitor, downloadable device, computer, Bluetooth compatible device, data sharing device, and combinations of any of the preceding.

11: A lens assembly for an electronic communications device, comprising:
an electronic communications device having a display module and at least one housing for securely holding said display module;
said display module having a lens with opposite stepped edges and opposite borderless edges extending between and connecting said stepped edge;
said housing having border sections comprising opposite stepped edge-engaging portions bordering said stepped edges of said lens, said stepped edge-engaging portions comprising opposite overlapping ledges for overlapping and securing said stepped edges of said lens; and
said borderless edges being spaced from said overlapping edges and being fully visible to a user.

12: A lens assembly for an electronic communications device in accordance with claim 11 wherein:
said stepped edges comprise stepped tabs;
said borderless edges comprise exposed edges; and
said electronic communications device comprises a seal for sealing said exposed edges to said housing.

13: A lens assembly for an electronic communications device in accordance with claim 11 wherein:
said housing has longitudinal sides extending between and connecting said border sections;
said borderless edges extend in proximity to said longitudinal sides, and
said lens extending across said housing to a location above said longitudinal sides.

14: A lens assembly for an electronic communications device in accordance with claim 11 wherein said lens comprises an electronic visual display selected from the group consisting of: a display lens, glass lens, transparent lens, touch sensitive lens, haptic lens, screen, impact-resistant screen, display screen, touchscreen, screen with an accelerator, user interface, monitor, light emitting display, and combinations of any of the preceding.

15: A lens assembly for an electronic communications device in accordance with claim 11 wherein said electronic communications device comprises a portable electronic device selected from the group consisting of: a radiotelephone, cellular (cell) phone, mobile phone, smart phone, qwerty phone, flip phone, slider phone, android phone, tablet phone, camera phone, clamshell device, portable networking device, mobile communications device, personal digital assistant (PDA), wireless e-mail device, two way pager, internet communication device, android tablet, ipod, ipad, kindle, electronic reading device, incoming call notifier, answering machine, and combinations of any of the preceding.

16: A lens assembly for an electronic communications device, comprising:
an electronic communications device having a display module and a chassis comprising a modular housing assembly for securely holding said display module;
said display module comprising an electronic visual display for displaying images, said electronic visual display comprising an elongated generally rectangular stepped display lens with opposite stepped lateral edges and opposite borderless longitudinal edges extending longitudinally between and integrally connecting said stepped edges, said stepped lateral edges comprising substantially stepped edges including a stepped top lateral edge and a stepped bottom lateral edge, and said display lens having a touch sensitive haptic elongated lens surface;
said modular housing assembly having a front housing and a back housing for matingly engaging said front housing, said front housing having substantially parallel front lateral housing-edges and substantially parallel front longitudinal housing edges extending between and integrally connecting said front lateral housing-edges, said front housing having a bezel comprising a back portion for supporting said lens, said back housing providing a rearward housing and having substantially parallel back lateral housing-edges and substantially parallel back longitudinal housing edges extending between and integrally connecting said back lateral housing-edges, said back housing-edges being aligned in registration with said front housing-edges, one of said front lateral housing edges comprising a top edge positioned at a level above said other edges of said front housing, one of said back lateral housing edges comprising a bottom edge positioned at a level above said other edges of said back housing;
said top edge and bottom edge of said modular housing assembly being positioned generally opposite each other, said top and bottom edges comprising generally opposite lateral border sections comprising substantially symmetrical lateral stepped edge-engaging portions laterally bordering said stepped lateral edges of said lens, said stepped edge-engaging portions comprising opposite overlapping ledges for overlapping and securely locating engaging said stepped edges of said display lens, said overlapping ledges cooperating with said back plate portion to provide pockets defining stepped edges-receiving slots for securely receiving the stepped edges of said display lens; and
said borderless longitudinal edges of said display lens being spaced from said lateral border sections and being fully visible to a user.

17: A lens assembly for an electronic communications device in accordance with claim 16 wherein:
said stepped edges comprise stepped tabs;
said borderless edges comprise exposed edges;
said electronic communications devices includes a seal comprising a transparent adhesive for sealing said exposed edges to said modular housing assembly; and
said adhesive comprising an impact-resistant material to help protect the exposed edges.

18: A lens assembly for an electronic communications device in accordance with claim 16 wherein:
said borderless edges extend adjacent said longitudinal housing-edges; and
said lens surface extends across said modular housing assembly to a position above said longitudinal housing-sides.

19: A lens assembly for an electronic communications device in accordance with claim 16 wherein said display is selected from the group consisting of: a glass lens, transparent lens, touch sensitive lens, haptic lens, screen, impact-resistant screen, display screen, touchscreen, screen with an accelerator, user interface, monitor, light emitting display, and combinations of any of the preceding.

20: A lens assembly for an electronic communications device in accordance with claim 16 wherein said electronic communications device comprises a portable electronic device selected from the group consisting of: a radiotelephone, cellular (cell) phone, mobile phone, smart phone, qwerty phone, flip phone, slider phone, android phone, tablet phone, camera phone, clamshell device, portable networking device, mobile communications device, personal digital assistant (PDA), wireless e-mail device, two way pager, internet communication device, android tablet, ipod, ipad, kindle, electronic reading device, incoming call notifier, answering machine, and combinations of any of the preceding.
